(19) United States
(12) Patent Application Publication
(10) Pub. No.: US 2026/0305367 A1
(43) Pub. Date: Oct. 1, 2026

(54) SEMICONDUCTOR DEVICE, MODULE MEMBER, AND CIRCUIT BOARD

(71) Applicant: Murata Manufacturing Co., Ltd., Kyoto-fu (JP)

(72) Inventors: Yoshimasa YOSHIOKA, Nagaokakyo-shi (JP); Hiroshi NAKAGAWA, Nagaokakyo-shi (JP)

(73) Assignee: Murata Manufacturing Co., Ltd., Kyoto-fu (JP)

(21) Appl. No.: 19/688,191

(22) Filed: May 26, 2026

Related U.S. Application Data
(63) Continuation of application No. PCT/JP2024/019382, filed on May 27, 2024.

(30) Foreign Application Priority Data
Nov. 28, 2023 (JP) 2023-200783

(51) Int. Cl. H10W 44/00

(52) U.S. Cl. CPC H10W 44/601

(57) ABSTRACT

A semiconductor device capable of reducing the influence of noise on a capacitance section. The semiconductor device includes a semiconductor substrate having one main surface and another main surface spaced apart from the one main surface in a thickness direction and facing in an opposite direction from the one main surface in the thickness direction, the semiconductor substrate having at least one trench provided in the one main surface, and a hole provided so as to extend along the thickness direction, open in at least one of the one main surface and the other main surface, and have a larger area than one of the trenches when viewed along the thickness direction; a capacitance section provided at least inside the trench and including a dielectric layer and two electrode layers sandwiching the dielectric layer therebetween; and a filling portion provided inside the hole and containing a conductive material.

### CROSS-REFERENCE TO RELATED APPLICATIONS

This application claims benefit of priority to International Patent Application No. PCT/JP 2024/019382, filed May 27, 2024, and to Japanese Patent Application No. 2023-200783, filed Nov. 28, 2023, the entire contents of each are incorporated herein by reference.

### BACKGROUND

### Technical Field

The present disclosure relates to a semiconductor device in which a capacitance section is provided inside a trench.

### Background Art

As an example of a semiconductor device in which a capacitance section is provided inside a trench, Japanese Patent No. 7052867 discloses a capacitor including a substrate having a recess in a surface thereof, and a dielectric film and a conductive film provided inside the recess.

### SUMMARY

In semiconductor devices in which a capacitance section is provided inside a trench, there is still room for improvement in terms of reducing the influence of noise on the capacitance section.

Therefore, the present disclosure provides a semiconductor device, a module member, and a circuit board that can reduce the influence of noise on a capacitance section.

A semiconductor device according to the present disclosure includes a semiconductor substrate having one main surface and another main surface spaced apart from the one main surface in a thickness direction and facing in an opposite direction from the one main surface in the thickness direction, the semiconductor substrate having at least one trench provided in the one main surface and a hole provided so as to extend along the thickness direction, open in at least one of the one main surface and the other main surface, and have a larger area than one of the trenches when viewed along the thickness direction. The semiconductor device further includes a capacitance section provided at least inside the trench and including a dielectric layer and two electrode layers sandwiching the dielectric layer therebetween; and a filling portion provided inside the hole and containing a conductive material.

In addition, a module member according to the present disclosure includes the semiconductor device; an electronic component; and a mounting substrate provided with the semiconductor device, the mounting substrate having a front mounting surface on which the electronic component is mounted and a rear mounting surface on a back side relative to the front mounting surface.

Furthermore, a circuit board according to the present disclosure includes the module member; and a main substrate having the module member mounted on a front surface thereof.

The semiconductor device is positioned between the mounting substrate and the main substrate.

According to present disclosure, it is possible to provide a semiconductor device, a module member, and a circuit board capable of reducing the influence of noise on a capacitance section.

### BRIEF DESCRIPTION OF THE DRAWINGS

FIG. 1 is a plan view of a semiconductor device according to an embodiment of the present disclosure;

FIG. 2 is a schematic cross-sectional view illustrating a cross section taken along line II-II in FIG. 1;

FIG. 3 is an equivalent circuit diagram of a semiconductor device according to an embodiment of the present disclosure;

FIG. 4 is a schematic cross-sectional view illustrating a method for manufacturing a semiconductor device according to an embodiment of the present disclosure;

FIG. 5 is a schematic cross-sectional view illustrating a method for manufacturing a semiconductor device according to an embodiment of the present disclosure;

FIG. 6 is a schematic cross-sectional view illustrating a method for manufacturing a semiconductor device according to an embodiment of the present disclosure;

FIG. 7 is a schematic cross-sectional view illustrating a method for manufacturing a semiconductor device according to an embodiment of the present disclosure;

FIG. 8 is a schematic cross-sectional view illustrating a method for manufacturing a semiconductor device according to an embodiment of the present disclosure;

FIG. 9 is a schematic cross-sectional view illustrating a method for manufacturing a semiconductor device according to an embodiment of the present disclosure;

FIG. 10 is a schematic cross-sectional view illustrating a method for manufacturing a semiconductor device according to an embodiment of the present disclosure;

FIG. 11 is a schematic cross-sectional view of a modification of a semiconductor device according to an embodiment of the present disclosure;

FIG. 12 is a schematic cross-sectional view of a modification of a semiconductor device according to an embodiment of the present disclosure;

FIG. 13 is a schematic cross-sectional view of a modification of a semiconductor device according to an embodiment of the present disclosure;

FIG. 14 is a schematic cross-sectional view of a modification of a semiconductor device according to an embodiment of the present disclosure;

FIG. 15 is a schematic cross-sectional view of a module member according to an embodiment of the present disclosure;

FIG. 16 is a schematic cross-sectional view of a modification of a module member according to an embodiment of the present disclosure;

FIG. 17 is a schematic cross-sectional view of a modification of a module member according to an embodiment of the present disclosure; and

FIG. 18 is a schematic cross-sectional view of a circuit board according to an embodiment of the present disclosure.

### DETAILED DESCRIPTION

An example of the present disclosure is described below with reference to the accompanying drawings. The following description is essentially illustrative and is not intended to limit present disclosure, applications, or uses thereof. Furthermore, the drawings are schematic drawings, and the proportions of the dimensions, etc., do not necessarily correspond to the actual ones. In addition, in the following description, terms indicating specific directions or positions (e.g., terms including “up”, “down”, “right”, “left”, “front”, and “back”) are used as necessary. However, the use of terms indicating specific directions or positions is for the purpose of facilitating the understanding of the present disclosure with reference to the drawings, and the meaning of these terms is not intended to limit the technical scope of the present disclosure.

### Semiconductor Device

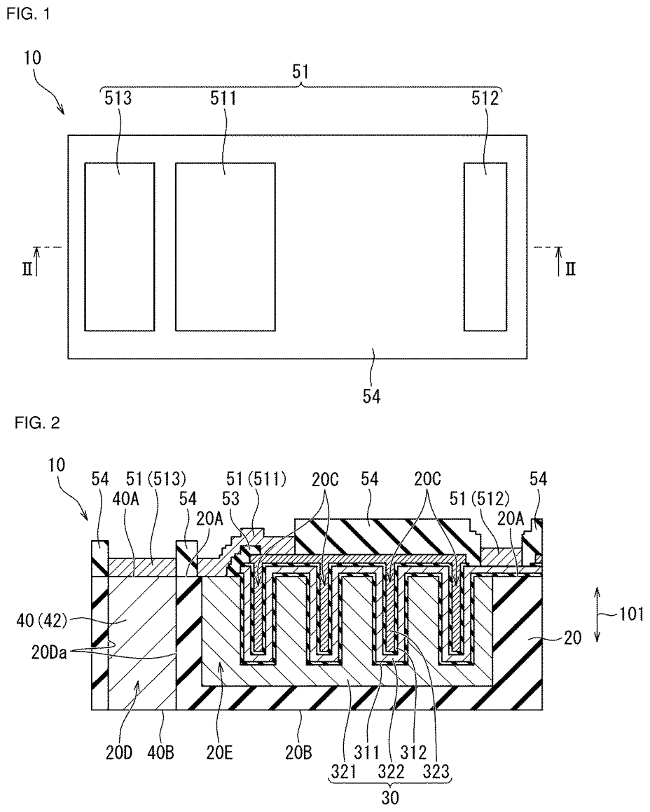

FIG. 1 is a plan view of a semiconductor device according to an embodiment of the present disclosure. FIG. 2 is a schematic cross-sectional view illustrating a cross section taken along line II-II in FIG. 1.

As illustrated in FIGS. 1 and 2, a semiconductor device 10 includes a semiconductor substrate 20, a capacitance section 30, a filling portion 40, a first insulating layer 53, a second insulating layer 54, and outer terminals 51.

The semiconductor substrate 20 is, for example, a silicon (Si) substrate, formed of high-resistance Si having insulating properties.

The semiconductor substrate 20 has one main surface 20A and another main surface 20B. The one main surface 20A and the other main surface 20B are spaced apart from each other in a thickness direction 101 of the semiconductor substrate 20. The one main surface 20A and the other main surface 20B face in opposite directions from each other in the thickness direction 101.

The semiconductor substrate 20 includes a recess 20E and four trenches 20C.

The recess 20E is filled with a first electrode layer 321 of the capacitance section 30, which will be described later. The first electrode layer 321 constitutes a part of the one main surface 20A of the semiconductor substrate 20. In this embodiment, the first electrode layer 321 constitutes both part of the capacitance section 30 and part of the semiconductor substrate 20.

Although one recess 20E is illustrated in FIG. 2, the semiconductor substrate 20 is not limited to having only one recess 20E. The semiconductor substrate 20 may have multiple recesses 20E.

The four trenches 20C are provided in a portion of the first electrode layer 321 that constitutes part of the one main surface 20A, and are recessed in the thickness direction 101. In other words, each of the four trenches 20C is a recess provided in the one main surface 20A.

The shape of the trenches 20C is arbitrary. For example, the trenches 20C may have a circular or rectangular shape when viewed along the thickness direction 101, or may be narrow grooves that curve or extend straight. The grooves may branch into multiple sections. The four trenches 20C may have the same shape or different shapes.

Although four trenches 20C are illustrated in FIG. 2, the semiconductor substrate 20 is not limited to having four trenches 20C. It is sufficient that the semiconductor substrate 20 has at least one trench 20C.

In FIG. 2, the recess 20E and the trenches 20C are provided in the one main surface 20A, but the recess 20E and the trenches 20C may also be provided in the other main surface 20B, or may be provided in both the one main surface 20A and the other main surface 20B.

The semiconductor substrate 20 has a hole 20D. The hole 20D penetrates through the semiconductor substrate 20 in the thickness direction 101. That is, the hole 20D extends in the thickness direction 101 and opens at the one main surface 20A and the other main surface 20B. The hole 20D has a side surface 20Da. The hole 20D has a circular shape when viewed along the thickness direction 101. That is, the hole 20D has a cylindrical shape.

The hole 20D does not have to penetrate through the semiconductor substrate 20 in the thickness direction 101. In other words, the hole 20D may open at only one of the one main surface 20A and the other main surface 20B. For example, the hole 20D may be a recess provided in the one main surface 20A, as in the modification in FIG. 13 described later. Alternatively, for example, the hole 20D may be a recess provided in the other main surface 20B.

The shape of the hole 20D is arbitrary, similar to the shape of the trenches 20C. For example, the hole 20D may have a circular or rectangular shape when viewed along the thickness direction 101, or may be a narrow groove that curves or extends straight. The groove may branch into multiple sections.

When viewed along the thickness direction 101, the hole 20D has a larger area than each of the four trenches 20C. In other words, when viewed along the thickness direction 101, the hole 20D has a larger area than one trench 20C.

The width of the hole 20D is greater than the width of each of the four trenches 20C. Here, the width of the hole 20D is defined, for example, as follows. When the hole 20D has a circular shape when viewed along the thickness direction 101, the width of the hole 20D is the diameter of the circle When the hole 20D has a rectangular shape when viewed along the thickness direction 101, the width of the hole 20D is the length of the shorter sides of the rectangle. When the hole 20D is a narrow groove when viewed along the thickness direction 101, the width of the hole 20D is the width in a direction perpendicular to the direction in which the groove extends. The same stipulations apply to the width of the trenches 20C.

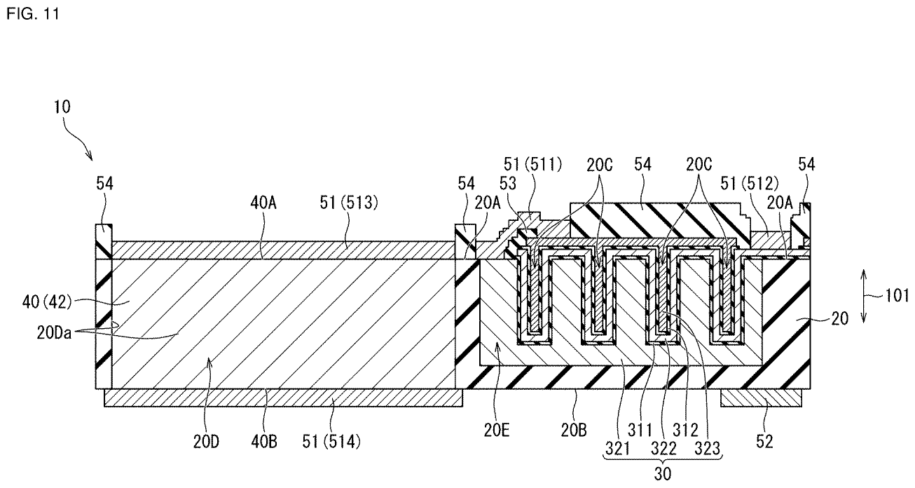

The width of the hole 20D is at least twice the width of each of the four trenches 20C (see FIG. 2). Preferably, the width of the hole 20D is at least five times the width of each of the four trenches 20C. Even more preferably, the width of the hole 20D is at least ten times the width of each of the four trenches 20C (see FIG. 11).

Although one hole 20D is illustrated in FIG. 2, the semiconductor substrate 20 is not limited to having only one hole 20D. The semiconductor substrate 20 may have multiple holes 20D.

The capacitance section 30 is provided inside the recess 20E, inside the trenches 20C, and on the one main surface 20A. In other words, the capacitance section 30 is provided at least inside the trench 20C.

The capacitance section 30 includes dielectric layers and electrode layers. In this embodiment, the capacitance section 30 includes two dielectric layers (a first dielectric layer 311 and a second dielectric layer 312) and three electrode layers (the first electrode layer 321, a second electrode layer 322, and a third electrode layer 323).

The dielectric layers contain a dielectric material. In this embodiment, the dielectric layers are composed of a dielectric material such as silicon dioxide (SiO₂), silicon nitride (Si₃N₄), hafnium oxide (HfO₂), or aluminum oxide (AlO). The first dielectric layer 311 and the second dielectric layer 312 may be composed of the same material or different materials.

The electrode layers contains a conductor. In this embodiment, the electrode layers are composed of a metal such as copper, low-resistance silicon (Si) such as n-type Si or p-type Si which has conductivity, or a conductor such as polysilicon (poly-Si). The first electrode layer 321, the second electrode layer 322, and the third electrode layer 323 may be composed of the same material or different materials.

The first electrode layer 321 is provided inside the recess 20E. In this embodiment, the first electrode layer 321 is composed of low-resistance silicon (Si). The first electrode layer 321 may be electrically connected to the other main surface 20B. As described above, the first electrode layer 321 has four trenches 20C in a portion that constitutes part of the one main surface 20A.

The first dielectric layer 311 is stacked on the first electrode layer 321 and the semiconductor substrate 20, both inside and outside the four trenches 20C. Inside the four trenches 20C, the first dielectric layer 311 is stacked on the first electrode layer 321 along the trenches 20C. Outside the four trenches 20C, the first dielectric layer 311 is stacked on the first electrode layer 321 and on the one main surface 20A of the semiconductor substrate 20.

The second electrode layer 322 is stacked on the first dielectric layer 311 both inside and outside the four trenches 20C. The second electrode layer 322 is stacked on the first dielectric layer 311 along the trenches 20C inside the four trenches 20C.

The second dielectric layer 312 is stacked on the second electrode layer 322 both inside and outside the four trenches 20C. Inside the four trenches 20C, the second dielectric layer 312 is stacked on the second electrode layer 322 along the trenches 20C.

The third electrode layer 323 is stacked on the second dielectric layer 312, both inside and outside the four trenches 20C. The third electrode layer 323 is stacked on the second dielectric layer 312 so as to fill the spaces, which are not illustrated, in the first dielectric layer 311, the second electrode layer 322, and the second dielectric layer 312 inside the four trenches 20C.

As described above, the dielectric layers and the electrode layers are stacked, so that the first dielectric layer 311 is sandwiched between the first electrode layer 321 and the second electrode layer 322, and the second dielectric layer 312 is sandwiched between the second electrode layer 322 and the third electrode layer 323. In other words, the capacitance section 30 includes at least a dielectric layer and two electrode layers sandwiching the dielectric layer therebetween. In this embodiment, the capacitance section 30 has two sets of a dielectric layer and two electrode layers sandwiching the dielectric layer therebetween. One of these two sets consists of the first dielectric layer 311 and the first electrode layer 321 and the second electrode layer 322 sandwiching the first dielectric layer 311 therebetween. The other of these two sets consists of the second dielectric layer 312 and the second electrode layer 322 and the third electrode layer 323 sandwiching the second dielectric layer 312 therebetween.

The capacitance section 30 may include only one set of a dielectric layer and two electrode layers sandwiching the dielectric layer therebetween, or may include three or more sets.

The filling portion 40 is provided inside the hole 20D. The filling portion 40 extends from one end portion to the other end portion of the hole 20D in the thickness direction 101. An upper surface 40A of the filling portion 40 is the portion of the filling portion 40 located at one end portion of the hole 20D in the thickness direction 101. The upper surface 40A of the filling portion 40 constitutes part of the one main surface 20A of the semiconductor substrate 20. A lower surface 40B of the filling portion 40 is the portion of the filling portion 40 located at the other end portion of the hole 20D in the thickness direction 101. The lower surface 40B of the filling portion 40 constitutes part of the other main surface 20B of the semiconductor substrate 20.

The filling portion 40 contains a conductive material. In this embodiment, the filling portion 40 is constituted by a conductive layer 42 composed of copper as a conductive material. In this embodiment, the filling portion 40 is composed only of a conductive material, but the filling portion 40 may also contain materials other than conductive materials. An example in which the filling portion 40 contains materials other than conductive materials will be described later.

The first insulating layer 53 and the second insulating layer 54 are composed of an insulating material. The first insulating layer 53 and the second insulating layer 54 may be composed of inorganic or organic materials, as long as the materials have high insulating properties. The first insulating layer 53 is stacked so as to cover portions of exposed parts of the first electrode layer 321, the second electrode layer 322, the third electrode layer 323, the first dielectric layer 311, and the second dielectric layer 312 on the one main surface 20A side of the semiconductor substrate 20. The second insulating layer 54 is stacked so as to cover a portion of the one main surface 20A of the semiconductor substrate 20, and portions of exposed parts of the second dielectric layer 312, the second electrode layer 322, and the third electrode layer 323 on the one main surface 20A side of the semiconductor substrate 20.

The outer terminals 51 are provided on at least one of the one main surface 20A and the other main surface 20B. The outer terminals 51 are composed of a conductive material such as nickel (Ni) or gold (Au). In this embodiment, the outer terminals 51 have a multilayer structure consisting of copper (Cu), nickel, and gold. In this embodiment, the outer terminals 51 include a first outer terminal 511, a second outer terminal 512, and a third outer terminal 513. In this embodiment, the first outer terminal 511, the second outer terminal 512, and the third outer terminal 513 are all provided on the one main surface 20A side of the semiconductor substrate 20. The first outer terminal 511, the second outer terminal 512, and the third outer terminal 513 are insulated from each other by the second insulating layer 54. In this embodiment, the first outer terminal 511, the second outer terminal 512, and the third outer terminal 513 are composed of the same material, but may be composed of different materials.

The first outer terminal 511 is stacked on the first electrode layer 321, the third electrode layer 323, and the first insulating layer 53. As a result, the first outer terminal 511 is in contact with the first electrode layer 321 and the third electrode layer 323. In other words, the first electrode layer 321 and the third electrode layer 323 are electrically connected to each other via the first outer terminal 511.

On the other hand, the first insulating layer 53 is present between the first outer terminal 511 and the first dielectric layer 311, the second electrode layer 322, and the second dielectric layer 312. As a result, the first outer terminal 511 and the first dielectric layer 311, the second electrode layer 322, and the second dielectric layer 312 are insulated from each other by the first insulating layer 53.

The second outer terminal 512 is stacked on the second electrode layer 322. As a result, the second outer terminal 512 and the second electrode layer 322 are in contact with each other and are electrically connected to each other.

The third outer terminal 513 is stacked on the upper surface 40A of the filling portion 40. As a result, the third outer terminal 513 and the filling portion 40 are in contact with each other and are electrically connected to each other. The third outer terminal 513 is an example of an outer terminal.

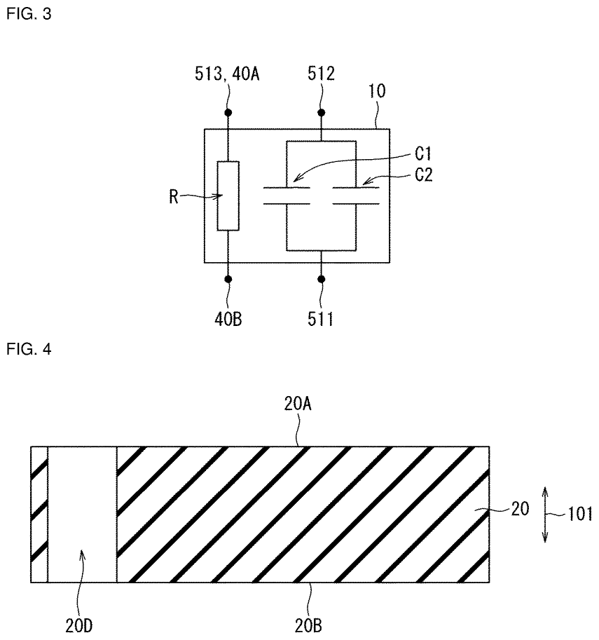

FIG. 3 is an equivalent circuit diagram of a semiconductor device according to an embodiment of the present disclosure. The semiconductor device 10, configured as described above, forms a circuit as illustrated in FIG. 3. However, the equivalent circuit of the semiconductor device 10 is not limited to the circuit illustrated in FIG. 3. For example, a resistor R and capacitors C1 and C2 may be connected to each other.

The capacitor C1 is formed by the first dielectric layer 311 and the first electrode layer 321 and the second electrode layer 322 sandwiching the first dielectric layer 311 therebetween, as illustrated in FIG. 3. The capacitor C2 is formed by the second dielectric layer 312 and the second electrode layer 322 and the third electrode layer 323 sandwiching the second dielectric layer 312 therebetween. One electrode of the capacitor C1 (first electrode layer 321) and one electrode of the capacitor C2 (third electrode layer 323) are connected to the first outer terminal 511. The other electrodes of the capacitors C1 and C2 (second electrode layer 322) are connected to the second outer terminal 512.

The filling portion 40 constitutes the resistor R. One end of the resistor R (the upper surface 40A of the filling portion 40) is connected to the third outer terminal 513. In this embodiment, the other end of the resistor R (the lower surface 40B of the filling portion 40) is not connected to an outer terminal, but may be connected to an outer terminal. An example in which the lower surface 40B of the filling portion 40 is connected to an outer terminal will be described later.

The semiconductor device 10 described above has the following dimensions, for example. More specifically, the length in the thickness direction 101 is 0.15 mm, the length in a width direction 103 is 0.6 mm, and the length in a depth direction, which is perpendicular to the thickness direction 101 and the width direction 103, is 0.3 mm. The depth (length in the thickness direction 101) of a first trench 20Ca and a second trench 20Cb is 30 μm. The thickness of the electrode layers (first electrode layer 321, second electrode layer 322, and third electrode layer 323) is 1000 nm. When the electrode layers are composed of titanium nitride (TiN), the thickness of the electrode layers is 20 nm. The thickness of the dielectric layers (first dielectric layer 311 and second dielectric layer 312) is 10 nm.

### Method for Manufacturing Semiconductor Device

A method for manufacturing the semiconductor device 10 according to an embodiment of the present disclosure will be described below with reference to FIGS. 4 to 10 and FIG. 2. FIGS. 4 to 10 are schematic cross-sectional views illustrating a method for manufacturing a semiconductor device according to an embodiment of the present disclosure.

The semiconductor device 10 is manufactured by dividing a multilayer body into multiple individual components. The multilayer body is an integrated structure in which multiple semiconductor devices 10 are arranged. In FIGS. 4 to 10, for the sake of explanation, only a portion of the multilayer body corresponding to one semiconductor device 10 is illustrated. The method for manufacturing the semiconductor device 10 according to this embodiment includes a hole formation step, a filling portion formation step, a capacitance section formation step (electrode layer formation step, dielectric layer formation step, and trench formation step), a first insulating layer formation step, a second insulating layer formation step, an outer terminal formation step, and a division step.

### Hole Formation Step

First, a hole formation step is performed. In the hole formation step, as illustrated in FIG. 4, the hole 20D, which penetrates through the semiconductor substrate 20 in the thickness direction 101, is formed in the semiconductor substrate 20. For example, a hard mask is formed on the semiconductor substrate 20, a pattern corresponding to the hole 20D is formed in the hard mask, and deep silicon etching is performed to form the hole 20D in the semiconductor substrate 20. After deep silicon etching is performed, the hard mask is removed.

### Filling Portion Formation Step

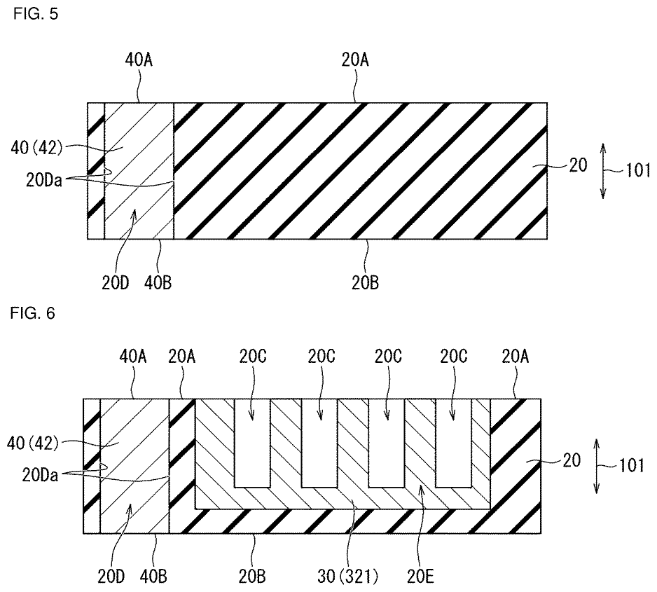

Next, the filling portion formation step is performed. In the filling portion formation step, as illustrated in FIG. 5, the hole 20D is filled with a conductive paste. This paste corresponds to the conductive layer 42 of the filling portion 40. For example, the filling portion 40 is formed by forming a seed, performing filled via plating, removing the seed, and flattening the surfaces. The filling portion 40 may be filled using methods other than that described above. For example, a conductive material such as copper (Cu) or aluminum (Al) may be used as the filling portion 40 and the conductive material may be filled using methods such as sputtering, wet plating, and paste application.

### Capacitance Section Formation Step

Next, the capacitance section formation step is performed. The capacitance section formation step is divided into an electrode layer formation step, a dielectric layer formation step, and a trench formation step.

In the capacitance section formation step, the electrode layer formation step and the dielectric layer formation step are performed in an alternating manner. The trench formation step is performed after the first electrode layer formation step and before the first dielectric layer formation step.

In the first electrode layer formation step, as illustrated in FIG. 6, the semiconductor substrate 20, which is formed as a high-resistance portion using high-resistance Si, is doped with impurities. As a result, the recess 20E is formed in the semiconductor substrate 20 as a high-resistance portion, and the first electrode layer 321, which is formed as a low-resistance portion, is formed inside the recess 20E. The first electrode layer 321 is formed, for example, by forming a patterned resist at the location of the recess 20E, performing etching of silicon doped with impurities, and then removing the resist.

In the trench formation step, four trenches 20C are formed in a portion of the one main surface 20A of the first electrode layer 321. The trenches 20C are formed, for example, by performing hard mask patterning and deep silicon etching, similar to the hole 20D.

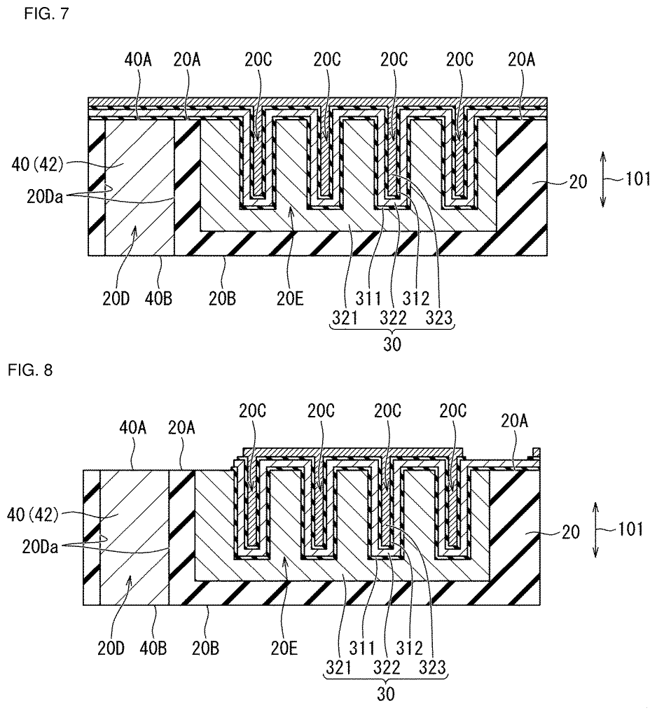

Next, the dielectric layer formation step and the electrode layer formation step are performed in an alternating manner. As a result, dielectric layers and electrode layers are alternately stacked along the one main surface 20A of the semiconductor substrate 20 and along the surface constituting the trenches 20C. Specifically, as illustrated in FIG. 7, the first dielectric layer 311 is formed on the semiconductor substrate 20, the filling portion 40, and the first electrode layer 321. The second electrode layer 322 is formed on the first dielectric layer 311. The second dielectric layer 312 is formed on the second electrode layer 322. The third electrode layer 323 is formed on the second dielectric layer 312. Thus, in the capacitance section formation step, a capacitance section including a dielectric layer and two electrode layers sandwiching the dielectric layer therebetween is formed in at least the trenches 20C in the semiconductor substrate 20.

In the dielectric layer formation step and the electrode layer formation step, after the formation of each of the dielectric layers 311 and 312 and each of the electrode layers 322 and 323, photolithography and etching are performed on each of the dielectric layers 311 and 312 and each of the electrode layers 322 and 323. As a result, as illustrated in FIG. 8, a portion of each of the dielectric layers 311 and 312 and each of the electrode layers 322 and 323 is removed.

In this embodiment, the trench formation step is defined as part of the capacitance section formation step. However, the trench formation step may be defined separately from the capacitance section formation step. In this case, the capacitance section formation step is divided into an electrode layer formation step and a dielectric layer formation step. Then, after the electrode layer formation step of the first capacitance section formation step is performed, the trench formation step is performed, and then the remaining steps of the capacitance section formation step are performed.

### First Insulating Layer Formation Step

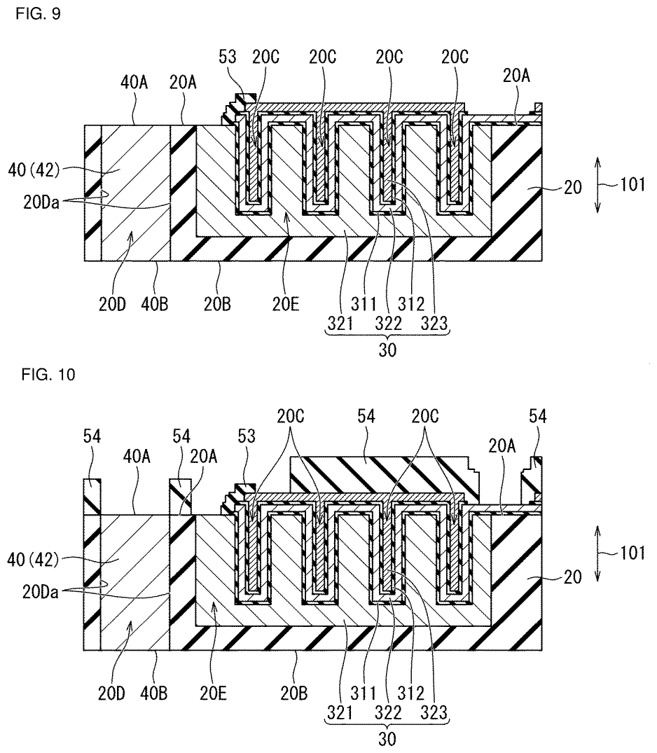

Next, the first insulating layer formation step is performed. In the first insulating layer formation step, the first insulating layer 53 is stacked as illustrated in FIG. 9. Specifically, the first insulating layer 53 is deposited on the upper surface in FIG. 8 (the surface on the one main surface 20A side) and patterned at a position corresponding to the first insulating layer 53 in FIG. 9 by performing photolithography and dry etching.

### Second Insulating Layer Formation Step

Next, the second insulating layer formation step is performed. In the second insulating layer formation step, the second insulating layer 54 is stacked as illustrated in FIG. 10. Specifically, the second insulating layer 54 is deposited on the upper surface in FIG. 9 (the surface on the one main surface 20A side) and patterned at a position corresponding to the second insulating layer 54 in FIG. 10 by performing photolithography and dry etching. Note that the second insulating layer formation step may be performed before the first insulating layer formation step or in parallel with the first insulating layer formation step.

The first insulating layer 53 and the second insulating layer 54 may be formed by means other than deposition, such as chemical vapor deposition (CVD), or by known means such as spin coating or film lamination. Furthermore, if necessary, a protective layer, which is an additional insulating layer, may be provided on the second insulating layer 54. For example, the protective layer may be composed of an epoxy, polyimide, or acrylic organic resin.

### Outer Terminal Formation Step

Next, the outer terminal formation step is performed. In the outer terminal formation step, as illustrated in FIG. 2, the outer terminals 51 (first outer terminal 511, second outer terminal 512, and third outer terminal 513) are formed. Specifically, the conductive layer for the outer terminals 51 is formed at predetermined positions (the positions illustrated in FIG. 2) on the upper surface (the surface on the one main surface 20A side) in FIG. 10 by known means such as metal sputtering, electroless plating, or paste application. Note that the outer terminals 51 may be composed of multiple conductive layers. By constructing the outer terminals 51 with multiple conductive layers, the outer terminals 51 have resistance to electrochemical migration while having improved barrier properties and solder wettability.

### Division Step

Next, the division step is performed. In the division step, the thickness of the semiconductor device 10 is adjusted, and the multilayer body in which multiple semiconductor devices 10 are arranged is cut into multiple semiconductor devices 10.

According to this embodiment, the filling portion 40 containing a conductive material can function as a shield against noise. In this way, the filling portion 40 can reduce noise that travels from outside the capacitance section 30 to the capacitance section 30 via the filling portion 40.

By using the filling portion 40 as wiring in the semiconductor device 10, the amount of wiring routed in the semiconductor device 10 can be reduced. This reduces parasitic capacitances that occur in the semiconductor device 10.

In the capacitor disclosed in Japanese Patent No. 7052867, a dielectric film and a conductive film are provided on the front surface side of the substrate, and therefore it not always easy to handle signals from the back surface side of the substrate. However, according to this embodiment, the hole 20D can open at both the one main surface 20A and the other main surface 20B, in other words, the hole 20D can penetrate through the semiconductor substrate 20 in the thickness direction 101. In this case, even if the capacitance section 30 is provided on the one main surface 20A side of the semiconductor substrate 20, signals from the other main surface 20B can be easily handled.

According to this embodiment, the area of the hole 20D is larger than the area of one trench 20C when viewed along the thickness direction 101. Therefore, manufacturing variations in the hole 20D can be reduced. As a result, filling of the filling portion 40 into the hole 20D is easy.

Hereinafter, modifications of this embodiment, and configurations of a module member 70 and a circuit board 1 will be described. In the following description, components described earlier are denoted by the same reference symbols, and descriptions thereof are generally omitted, although may be described as necessary.

### Modification 1 of Semiconductor Device

FIG. 11 is a schematic cross-sectional view of a modification of a semiconductor device according to an embodiment of the present disclosure.

As illustrated in FIG. 11, the semiconductor device 10 may include the outer terminals 51 on the other main surface 20B. The semiconductor device 10 illustrated in FIG. 11 includes a fourth outer terminal 514 as an outer terminal 51 on the other main surface 20B. The semiconductor device 10 may also include a dummy terminal 52 on at least one of the one main surface 20A and the other main surface 20B. The semiconductor device 10 illustrated in FIG. 11 includes the dummy terminal 52 on the other main surface 20B.

The fourth outer terminal 514 and the dummy terminal 52 are composed of a conductive material such as nickel (Ni) or gold (Au), similar to the first outer terminal 511, etc.

The fourth outer terminal 514 is stacked on the lower surface 40B of the filling portion 40. As a result, the fourth outer terminal 514 and the filling portion 40 are in contact with each other and electrically connected to each other.

The dummy terminal 52 is stack d on the other main surface 20B of the semiconductor substrate 20. The dummy terminal 52 is not electrically connected to other conductive parts of the semiconductor device 10. Other conductive parts include, for example, the first electrode layer 321, the second electrode layer 322, the third electrode layer 323, the filling portion 40, and the outer terminals 51.

According to Modification 1, when mounting the semiconductor device 10 on a substrate using a paste such as solder, the mounting can be easily performed by applying the paste to the outer terminals 51.

According to Modification 1, when mounting the semiconductor device 10 on a substrate using a paste such as solder, the mounting can be performed by applying the paste to the dummy terminal 52. In other words, according to Modification 1, when performing the mounting, more paste can be applied than would be possible for a semiconductor device that does not have the dummy terminal 52. As a result, the strength of the mounting can be increased.

### Modification 2 of Semiconductor Device

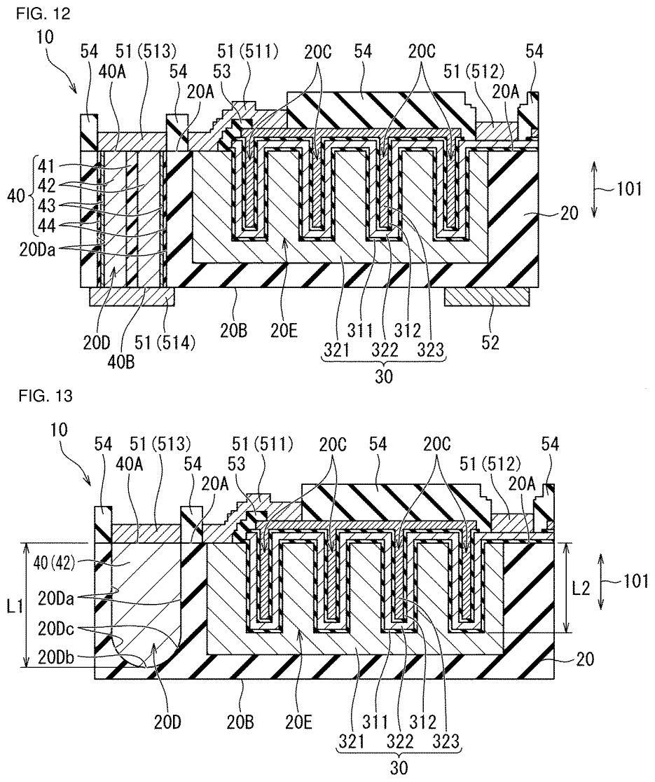

FIG. 12 is a schematic cross-sectional view of a modification of a semiconductor device according to an embodiment of the present disclosure.

As illustrated in FIG. 12, the filling portion 40 may contain materials other than conductive materials. The filling portion 40 illustrated in FIG. 12 includes, in addition to the conductive layer 42, an embedded layer 41, a barrier layer 43, and an isolation layer 44.

The embedded layer 41 is composed of a resin such as epoxy. The barrier layer 43 contains conductive materials such as titanium nitride (TiN) and nickel (Ni). The isolation layer 44 is composed of insulating materials such as silicon dioxide (SiO₂) and silicon nitride (Si₃N₄). In other words, the filling portion 40 of the semiconductor device 10 illustrated in FIG. 12 contains conductive materials in the conductive layer 42 and the barrier layer 43, which constitute part of the filling portion 40, but does not contain conductive materials in the embedded layer 41 and the isolation layer 44, which constitute other parts the filling portion 40.

Each of the embedded layer 41, the conductive layer 42, the barrier layer 43, and the isolation layer 44 penetrates through the hole 20D in the thickness direction 101. In other words, each of the embedded layer 41, the conductive layer 42, the barrier layer 43, and the isolation layer 44 extends from one end portion to the other end portion of the hole 20D in the thickness direction 101.

Viewed along the thickness direction 101, the conductive layer 42 surrounds the embedded layer 41. Viewed along the thickness direction 101, the barrier layer 43 surrounds the conductive layer 42. Viewed along the thickness direction 101, the isolation layer 44 surrounds the barrier layer 43. The outer peripheral surface of the isolation layer 44 is in contact with the side surface 20Da of the hole 20D.

The filling portion 40 does not necessarily have to include at least one of the embedded layer 41 and the barrier layer 43. Furthermore, a magnetic layer 45, which is described later, may be provided between two adjacent layers among the embedded layer 41, the conductive layer 42, the barrier layer 43, and the isolation layer 44.

According to Modification 2, the isolation layer 44 is composed of an insulating material. Therefore, the isolation layer 44 can block the unintended propagation of electrical signals from the conductive layer 42 to other parts such as the capacitance section 30 via the semiconductor substrate 20.

For example, there is a risk of the electrical resistance of the conductive layer 42 changing due to the diffusion of conductive material (e.g., copper) contained in the conductive layer 42. According to Modification 2, the diffusion of the conductive layer 42 can be suppressed by the barrier layer 43. Therefore, a change in the electrical resistance of the conductive layer 42 can be reduced.

According to Modification 2, since the barrier layer 43 contains a conductive material, the barrier layer 43 can function as a seed layer. Furthermore, electrical signals can be transmitted through the barrier layer 43.

According to Modification 2, by providing the embedded layer 41 in the filling portion 40, it is possible to suppress the occurrence of unnecessary voids, foreign matter contamination, and unevenness in the exposed portion of the filling portion 40 on one main surface 20A and the other main surface 20B. In other words, as a result of providing the embedded layer 41 in the filling portion 40, it is not necessary to fill the entire hole 20D with the conductive layer 42. Therefore, the manufacturing cost of the semiconductor device 10 can be reduced.

### Modification 3 of Semiconductor Device

FIG. 13 is a schematic cross-sectional view of a modification of a semiconductor device according to an embodiment of the present disclosure.

As illustrated in FIG. 13, the hole 20D may be open at one of the one main surface 20A and the other main surface 20B and have a bottom at the other one of the one main surface 20A and the other main surface 20B. In Modification 3 illustrated in FIG. 13, the hole 20D opens at the one main surface 20A and has a bottom at the other main surface 20B side. The hole 20D includes the side surface 20Da and a bottom surface 20Db. The side surface 20Da extends from one of the one main surface 20A and the other main surface 20B to the other one of the one main surface 20A and the other main surface 20B. In Modification 3 illustrated in FIG. 13, the side surface 20Da extends from the one main surface 20A to the other main surface 20B. The bottom surface 20Db is connected to an end portion of the side surface 20Da at the side where the other one of the one main surface 20A and the other main surface 20B is located. In Modification 3 illustrated in FIG. 13, the bottom surface 20Db is connected to the end portion of the side surface 20Da on the other main surface 20B side. In Modification 3, a boundary portion 20Dc between the side surface 20Da and the bottom surface 20Db is a curved surface. In other words, the boundary portion 20Dc between the side surface 20Da and the bottom surface 20Db does not have corners.

The hole 20D may be open at the other main surface 20B and have a bottom on the one main surface 20A side.

The hole 20D is deeper than the trench 20C. A length L1 of the hole 20D in the thickness direction 101 is greater than a length L2 of the trenches 20C in the thickness direction 101.

According to Modification 3, the hole 20D has a bottom. That is, the hole 20D does not penetrate all the way through in the thickness direction 101. Therefore, according to Modification 3, the aspect ratio of the hole 20D can be made smaller compared to a configuration in which the hole 20D penetrates all the way through in the thickness direction 101. As a result, it is easy to fill the hole 20D with a conductive material.

If the boundary portion 20Dc between the side surface 20Da and the bottom surface 20Db in the hole 20D is not a curved surface but is bent and has an angle, there is a risk that when the conductive material is filled into the hole 20D, the conductive material will not be filled into the corner portion, resulting in a void. According to Modification 3, since the boundary portion 20Dc between the side surface 20Da and the bottom surface 20Db in the hole 20D is a curved surface, it is possible to eliminate or reduce voids when filling the hole 20D with the conductive material.

According to Modification 3, compared to a configuration in which the length L1 of the hole 20D in the thickness direction 101 is less than or equal to the length L2 of the trenches 20C in the thickness direction 101, noise traveling from outside the capacitance section 30 to the capacitance section 30 via the filling portion 40 can be reliably suppressed.

According to Modification 3, when grinding down the other main surface 20B side of the semiconductor substrate 20, the hole 20D can be opened at the other main surface 20B without opening the trenches at the other main surface 20B. By not opening the trenches 20C at the other main surface 20B, it is possible to suppress damage to the characteristics (in other words, capacitance) of the capacitance section 30.

### Modification 4 of Semiconductor Device

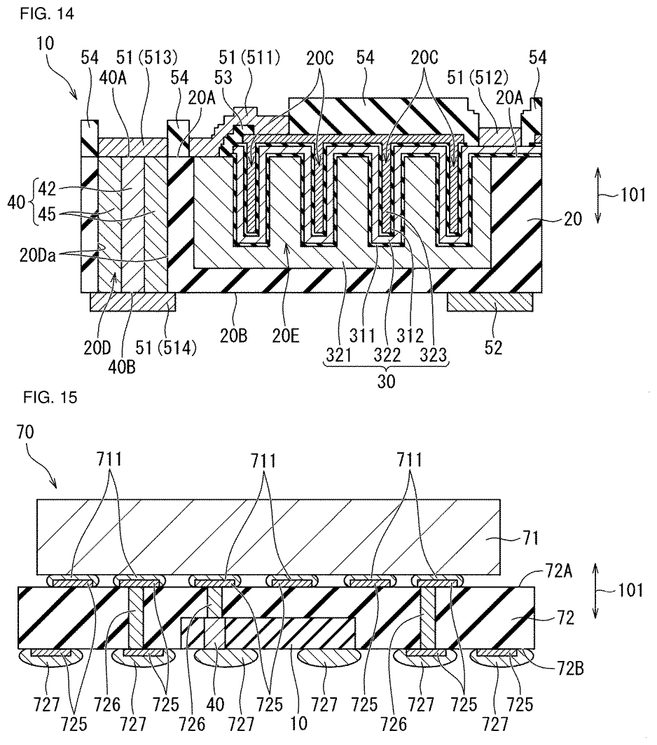

FIG. 14 is a schematic cross-sectional view of a modification of a semiconductor device according to an embodiment of the present disclosure.

As illustrated in FIG. 14, the filling portion 40 may contain a magnetic material. The filling portion 40 illustrated in FIG. 14 includes a magnetic layer 45 in addition to the conductive layer 42.

The magnetic layer 45 is composed of a magnetic material. In other words, in the semiconductor device 10 of Modification 4 illustrated in FIG. 14, the filling portion 40 contains a magnetic material in the magnetic layer 45, which is part of the filling portion 40, but does not contain a conductive material in the conductive layer 42, which is another part of the filling portion 40.

The magnetic material is, for example, spherical metallic magnetic powder. The most abundant element in the metallic magnetic powder is iron (Fe), and a median diameter D50 is 5 μm or less. The metallic magnetic powder is a composite material incorporating an organic resin such as epoxy, phenol, acrylic, and polyimide. Because the metallic powder is a composite material, insulation can be provided between the powder particles, and the semiconductor device 10 can be provided as an inductor component with low loss.

Each of the conductive layer 42 and the magnetic layer 45 extends through the hole 20D in the thickness direction 101. In other words, each of the conductive layer 42 and the magnetic layer 45 extends from one end portion to the other end portion of the hole 20D in the thickness direction 101.

When viewed in the thickness direction 101, the magnetic layer 45 surrounds the conductive layer 42. In other words, the conductive layer 42 penetrates through the magnetic layer 45 in the thickness direction 101. The outer peripheral surface of the magnetic layer 45 is in contact with the side surface 20Da of the hole 20D.

Note that the conductive layer 42 does not necessarily have to penetrate through the magnetic layer 45 in the thickness direction 101. For example, the conductive layer 42 may be provided on the capacitance section 30 side in the hole 20D and the magnetic layer 45 may be provided on the opposite side of the hole 20D from the capacitance section 30, so that the conductive layer 42 and the magnetic layer 45 are arranged side by side when viewed along the thickness direction 101.

According to Modification 4, the magnetic layer 45 can function as a magnetic shield. Furthermore, according to Modification 4, the filling portion 40 can function as an inductor.

According to Modification 4, the area of the hole 20D is greater than the area of one trench 20C when viewed along the thickness direction 101. Therefore, according to Modification 4, compared to a configuration in which the area of the hole 20D is less than or equal to the area of one trench 20C when viewed along the thickness direction 101, the Q value of the inductor can be increased when the filling portion 40 functions as an inductor.

### Module Member

FIG. 15 is a schematic cross-sectional view of a module member according to an embodiment of the present disclosure.

As illustrated in FIG. 15, a module member 70 includes the semiconductor device 10 according to any of the embodiments and modifications described above, an electronic component 71, and a mounting substrate 72 on and/or in which the semiconductor device 10 and the electronic component 71 are provided. Viewed along the thickness direction 101, the area of the mounting substrate 72 in FIG. 15 and FIGS. 16 to 18 described later is greater than the area of the semiconductor device 10, but may be less than or equal to the area of the semiconductor device 10.

The electronic component 71 is mounted on at least one of a front mounting surface 72A and a rear mounting surface 72B of the mounting substrate 72. In the configuration illustrated in FIG. 15, the electronic component 71 is mounted on the front mounting surface 72A. The electronic component 71 is an integrated circuit (IC), but is not limited to being an IC. For example, the electronic component 71 may be a resistor, an inductor, or the like.

The mounting substrate 72 illustrated in FIG. 15 is an interposer substrate. The mounting substrate 72 is composed of silicon, but may also be composed of a material other than silicon (for example, a ceramic). The interposer substrate is constructed by stacking organic resins such as build-up films on a base substrate while forming wiring. During this process, a portion of a build-up film can be opened and a component such as the electronic component 71 and the semiconductor device 10 can be embedded. Finally, the thickness can be made uniform by grinding down the build-up film and the embedded components. The mounting substrate 72 (interposer substrate) illustrated in FIG. 15 contains glass fibers. The inclusion of glass fibers increases the strength of the mounting substrate 72 and suppresses warping of the substrate.

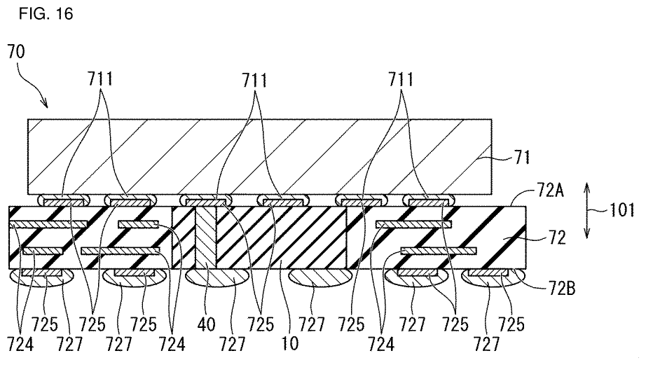

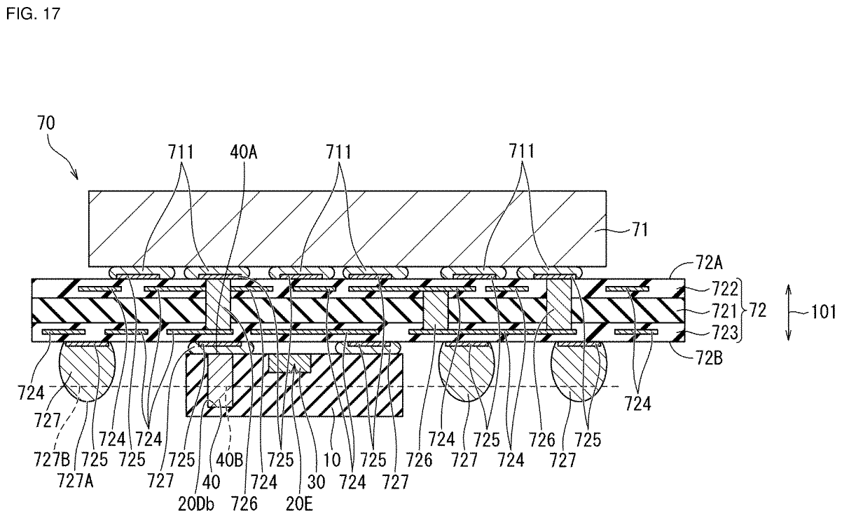

Note that the mounting substrate 72 illustrated in FIG. 15 is not limited to being an interposer substrate, and may also be a substrate composed of glass epoxy or the like (see FIG. 16), or a substrate including a core material 721 (see FIG. 17).

The mounting substrate 72 has the front mounting surface 72A and the rear mounting surface 72B. The rear mounting surface 72B is on the back side relative to the front mounting surface 72A. The front mounting surface 72A and the rear mounting surface 72B are spaced apart from each other in the thickness direction 101 of the mounting substrate 72. The front mounting surface 72A and the rear mounting surface 72B face in opposite directions from each other in the thickness direction 101.

The semiconductor device 10 is embedded in the mounting substrate 72. In the configuration illustrated in FIG. 15, a portion of the semiconductor device 10 is exposed to outside the mounting substrate 72 at the rear mounting surface 72B, and the portion of the semiconductor device 10 that is exposed to the outside constitutes a part of the rear mounting surface 72B. The semiconductor device 10 may also be completely embedded in the mounting substrate 72 so as not to be exposed to outside the mounting substrate 72. Alternatively, the semiconductor device 10 may be partially embedded in the mounting substrate 72 so that a portion thereof protrudes from the outside of the mounting substrate 72. As described above, at least a portion of the semiconductor device 10 is provided inside the mounting substrate 72.

When viewed along the thickness direction 101, at least a portion of the semiconductor device 10 and at least a portion of the electronic component 71 are located at an overlapping position. In the configuration illustrated in FIG. 15 and the configurations illustrated in FIGS. 16 to 18 described later, when viewed along the thickness direction 101, the entire semiconductor device 10 is at an overlapping position with the electronic component 71.

The mounting substrate 72 includes outer electrodes 725 and through electrodes 726. The outer electrodes 725 and the through electrodes 726 are composed of a conductive material such as copper.

The outer electrodes 725 are provided on at least one of the front mounting surface 72A and the rear mounting surface 72B. In the configuration illustrated in FIG. 15, the outer electrodes 725 are provided on both the front mounting surface 72A and the rear mounting surface 72B.

The outer electrodes 725 provided on the front mounting surface 72A are electrically connected to the electronic component 71 via solder 711. In the configuration illustrated in FIG. 15, the outer electrodes 725 provided on the rear mounting surface 72B are not electrically connected to the electronic component 71, but may be electrically connected to the electronic component 71 via solder 727.

The through electrodes 726 penetrate through the mounting substrate 72 in the thickness direction 101 by filling through holes that penetrate through the mounting substrate 72 in the thickness direction 101. In the configuration illustrated in FIG. 15, the through electrodes 726 are through-silicon vias (TSV).

The outer electrodes 725, the through electrodes 726, the filling portion 40 of the semiconductor device 10, and the solder 711 and 727 can be electrically connected to each other. For example, in the configuration illustrated in FIG. 15, the through electrodes 726 and the outer electrodes 725 are electrically connected, and the filling portion 40 of the semiconductor device 10 is electrically connected to the through electrodes 726 and the solder 727.

According to this embodiment, the semiconductor device 10 can be placed close to the electronic component 71. As a result, the signal integrity (SI) of the semiconductor device 10 can be improved.

### Modification 1 of Module Member

FIG. 16 is a schematic cross-sectional view of a modification of a module member according to an embodiment of the present disclosure.

As illustrated in FIG. 16, a portion of the semiconductor device 10 may be exposed to outside the mounting substrate 72 at both the front mounting surface 72A and the rear mounting surface 72B.

In the configuration illustrated in FIG. 16, the portion of the semiconductor device 10 exposed at the front mounting surface 72A constitutes a part of the front mounting surface 72A, and the portion of the semiconductor device 10 exposed at the rear mounting surface 72B constitutes a part of the rear mounting surface 72B. In other words, the length of the semiconductor device 10 in the thickness direction 101 and the length of the mounting substrate 72 in the thickness direction 101 are the same or approximately the same.

The mounting substrate 72 illustrated in FIG. 16 is a substrate composed of glass epoxy or the like. Note that the mounting substrate 72 illustrated in FIG. 16 may be, for example, an interposer substrate (see FIG. 15) or a substrate including the core material 721 (see FIG. 17).

The mounting substrate 72 illustrated in FIG. 16 includes the outer electrodes 725 and inner electrodes 724. The outer electrodes 725 and the inner electrodes 724 are composed of a conductive material such as copper. The inner electrodes 724 are located inside the mounting substrate 72. The filling portion 40 of the semiconductor device 10 is electrically connected to the outer electrodes 725 and the solder 727.

Although not illustrated in FIG. 16, the inner electrodes 724 may be connected to the outer electrodes 725, the filling portion 40 of the semiconductor device 10, and other inner electrodes 724, etc., via the through electrodes 726. The inner electrodes 724, the outer electrodes 725, the through electrodes 726, the filling portion 40 of the semiconductor device 10, and the solder 711 and 727 may be electrically connected to each other.

According to Modification 1, the thickness of the semiconductor device 10 can be made the same as the thickness of the mounting substrate 72. This makes it possible to improve the characteristics of the capacitance section 30 compared to a configuration in which the thickness of the semiconductor device 10 is smaller than the thickness of the mounting substrate 72. For example, the capacitance can be increased.

### Modification 2 of Module Member

FIG. 17 is a schematic cross-sectional view of a modification of a module member according to an embodiment of the present disclosure.

As illustrated in FIG. 17, the semiconductor device 10 may be mounted on a surface of the mounting substrate 72. In other words, the semiconductor device 10 may be provided outside the mounting substrate 72.

In the configuration illustrated in FIG. 17, the electronic component 71 is mounted on the front mounting surface 72A, and the semiconductor device 10 is mounted on the rear mounting surface 72B. However, the electronic component 71 may be mounted on the rear mounting surface 72B, the semiconductor device 10 may be mounted on the front mounting surface 72A, or both the electronic component 71 and the semiconductor device 10 may be mounted on the same mounting surface. Furthermore, each of the electronic component 71 and the semiconductor device 10 may be mounted on both the front mounting surface 72A and the rear mounting surface 72B.

The mounting substrate 72 illustrated in FIG. 17 includes the core material 721 and insulating substrates 722 and 723 provided so as to sandwich the core material 721 therebetween in the thickness direction 101. The inner electrodes 724 are provided inside the insulating substrates 722 and 723. The surface of the insulating substrate 722 on the opposite side from the surface in contact with the core material 721 is the front mounting surface 72A of the mounting substrate 72. The surface of the insulating substrate 723 on the opposite side from the surface in contact with the core material 721 is the rear mounting surface 72B of the mounting substrate 72. The outer electrodes 725 are provided on the front mounting surface 72A and the rear mounting surface 72B. The through electrodes 726 can penetrate through at least one of the core material 721, the insulating substrate 722, and the insulating substrate 723. The through electrodes 726 can be electrically connected to the inner electrodes 724 and the outer electrodes 725.

The mounting substrate 72 illustrated in FIG. 17 may be, for example, an interposer substrate (see FIG. 15) or a substrate composed of glass epoxy or the like (see FIG. 16). Furthermore, although the semiconductor device 10 illustrated in FIG. 17 includes the filling portion 40 having a bottom, it may also include a filling portion 40 that penetrates through the semiconductor substrate 20 in the thickness direction 101.

According to Modification 2, the semiconductor device 10 can be disposed close to the electronic component 71. This reduces parasitic capacitances between the semiconductor device 10 and the electronic component 71.

### Circuit Board

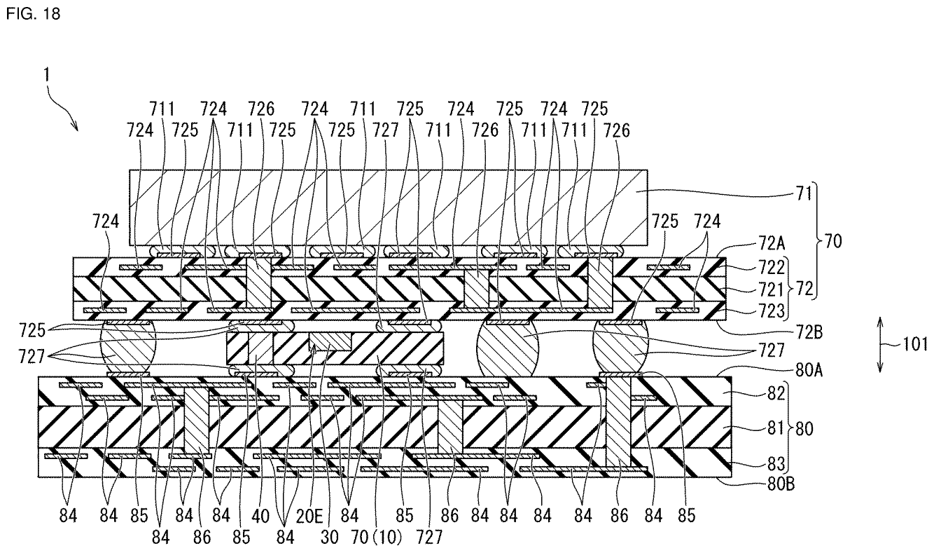

FIG. 18 is a schematic cross-sectional view of a circuit board according to an embodiment of the present disclosure.

As illustrated in FIG. 18, a circuit board 1 includes the module member 70 of Modification 2 illustrated in FIG. 17, and a main substrate 80 on which the module member 70 is mounted. Note that the circuit board 1 may also include the module member 70 of an embodiment other than Modification 2, instead of the module member 70 illustrated in FIG. 17. Viewed along the thickness direction 101, the area of the main substrate 80 in FIG. 18 is greater than the area of the mounting substrate 72, but may be less than or equal to the area of the mounting substrate 72. The thickness of the main substrate 80 in FIG. 18 is greater than the thickness of the mounting substrate 72, but may be less than or equal to the thickness of the mounting substrate 72.

The main substrate 80, like the mounting substrate 72 illustrated in FIG. 17, includes a core material 81 and insulating substrates 82 and 83 provided so as to sandwich the core material 81 therebetween in the thickness direction 101. In the configuration illustrated in FIG. 18, the core material 81 has the same configuration as the core material 721 of the mounting substrate 72, and the insulating substrates 82 and 83 have the same configuration as the insulating substrates 722 and 723 of the mounting substrate 72.

The main substrate 80 may be an interposer substrate, or a substrate composed of glass epoxy or the like.

The main substrate 80 has a front mounting surface 80A and a rear mounting surface 80B on the back side relative to the front mounting surface 80A. The front mounting surface 80A and the rear mounting surface 80B are spaced apart from each other in the thickness direction 101 of the main substrate 80. The front mounting surface 80A and the rear mounting surface 80B face in opposite directions from each other in the thickness direction 101. The surface of the insulating substrate 82 on the opposite side from the surface in contact with the core material 81 is the front mounting surface 80A of the main substrate 80. The surface of the insulating substrate 83 on the opposite side from the surface in contact with the core material 81 is the rear mounting surface 80B of the main substrate 80.

The main substrate 80 includes inner electrodes 84, outer electrodes 85, and through electrodes 86. The inner electrodes 84, the outer electrodes 85, and the through electrodes 86 are composed of a conductive material such as copper.

The inner electrodes 84 are located inside the main substrate 80, similar to the inner electrodes 724 of the mounting substrate 72. The outer electrodes 85 are located on at least one of the front mounting surface 80A and the rear mounting surface 80B, similar to the outer electrodes 725 of the mounting substrate 72. The through electrodes 86 may penetrate through at least one of the core material 81, the insulating substrate 82, and the insulating substrate 83, similar to the through electrodes 726 of the mounting substrate 72. The inner electrodes 84, outer electrodes 85, and through electrodes 86 can be electrically connected to each other.

The module member 70 can be mounted on at least one of the front mounting surface 80A and the rear mounting surface 80B. In the circuit board 1 illustrated in FIG. 18, the module member 70 is mounted on the front mounting surface 80A.

The semiconductor device 10 of the module member 70 is located between the mounting substrate 72 and the main substrate 80.

In the process of manufacturing the circuit board 1 illustrated in FIG. 18, a mounting step is performed in which the module member 70 illustrated in FIG. 17 is mounted on the main substrate 80. Prior to the mounting step, an exposure step is performed in which the filling portion 40 of the semiconductor device 10 included in the module member 70 illustrated in FIG. 17 is exposed.

In the module member 70 illustrated in FIG. 17, the semiconductor device 10 includes the filling portion 40 having a bottom. Furthermore, in the thickness direction 101, a tip portion 727A of the solder 727 is located nearer to the bottom surface 20Db of the hole 20D than the capacitance section 30.

In the exposure step, the semiconductor device 10 and the solder 727 are ground down at the position indicated by the dashed line in FIG. 17. The position indicated by the dashed line in FIG. 17 is between the tip portion 727A of the solder 727 and the capacitance section 30 in the thickness direction 101. As a result, the lower surface 40B of the filling portion 40 is exposed to the outside. In addition, the lower surface 40B of the filling portion 40 and a tip portion 727B of the solder 727 are located on the ground down surface (on the same plane) indicated by the dashed line in FIG. 17.

In the next mounting step, the module member 70 that has undergone the exposure step is mounted on the front mounting surface 80A of the main substrate 80. At this time, since the lower surface 40B of the filling portion 40 and the tip portion 727B of the solder 727 came to be located on the same plane during the exposure step, mounting is easy.

The exposure step enables the creation of a thin module member 70 on the main substrate 80 while maintaining good handling characteristics. Furthermore, the exposure process makes it possible to make the height of the semiconductor device 10 mounted on the rear mounting surface 72B of the mounting substrate 72 of the module member 70 the same as the height of the solder 727.

In this embodiment, the semiconductor device 10 is located between the mounting substrate 72 and the main substrate 80. In other words, when viewed along the thickness direction 101, the semiconductor device 10 and the mounting substrate 72 overlap. Therefore, the circuit board 1 can be reduced in size compared to a configuration in which the semiconductor device 10 and the mounting substrate 72 do not overlap when viewed along the thickness direction 101.

According to this embodiment, since the semiconductor device 10 is located between the mounting substrate 72 and the main substrate 80, the intrusion of external noise into the semiconductor device 10 can be reduced, for example, by shielding films provided on the mounting substrate 72 and the main substrate 80.

The semiconductor device 10, the module member 70, and the circuit board 1 described above can also be configured as follows.

A first aspect of the present disclosure provides a semiconductor device comprising a semiconductor substrate having one main surface and another main surface spaced apart from the one main surface in a thickness direction and facing in an opposite direction from the one main surface in the thickness direction, the semiconductor substrate having at least one trench provided in the one main surface, and a hole provided so as to extend along the thickness direction, open in at least one of the one main surface and the other main surface, and have a larger area than one of the trenches when viewed along the thickness direction; a capacitance section provided at least inside the trench and including a dielectric layer and two electrode layers sandwiching the dielectric layer therebetween; and a filling portion provided inside the hole and containing a conductive material.

A second aspect of the present disclosure provides the semiconductor device according to the first aspect, further comprising a conductive outer terminal provided on at least one of the one main surface and the other main surface, the outer terminal contacting the filling portion.

A third aspect of the present disclosure provides the semiconductor device according to the first or second aspect, further comprising a conductive dummy terminal provided on at least one of the one main surface and the other main surface, the dummy terminal not electrically connected to other conductive parts of the semiconductor device.

A fourth aspect of the present disclosure provides the semiconductor device according to any one of the first to third aspects, wherein the filling portion includes an embedded layer composed of resin, a conductive layer containing a conductive material and surrounding the embedded layer when viewed along the thickness direction, a barrier layer containing a conductive material and surrounding the conductive layer when viewed along the thickness direction, and an isolation layer composed of an insulating material and surrounding the barrier layer when viewed along the thickness direction.

A fifth aspect of the present disclosure provides the semiconductor device according to any one of the first to fourth aspects, wherein the hole is open at one of the one main surface and the other main surface, and has a bottom at another one of the one main surface and the other main surface.

A sixth aspect of the present disclosure provides the semiconductor device according to the fifth aspect, wherein the hole portion includes a side surface extending from one of the one main surface and the other main surface toward another one of the one main surface and the other main surface, and a bottom surface connected to an end portion of the side surface at a side where the other one of the one main surface and the other main surface is located, and a boundary portion between the side surface and the bottom surface is a curved surface.

A seventh aspect of the present disclosure provides the semiconductor device according to the fifth or sixth aspect, wherein a length of the hole in the thickness direction is greater than a length of the trench in the thickness direction.

An eighth aspect of the present disclosure provides the semiconductor device according to any one of the first to seventh aspects, wherein the filling portion includes a conductive layer containing a conductive material and extending from one end portion to another end portion of the hole in the thickness direction, and a magnetic layer containing a magnetic material and extending from the one end portion to the other end portion of the hole in the thickness direction.

A ninth aspect of the present disclosure provides the semiconductor device according to the eighth aspect, wherein the conductive layer penetrates through the magnetic layer in the thickness direction.

A tenth aspect of the present disclosure provides a module member comprising the semiconductor device according to any one of the first to ninth aspects; an electronic component; and a mounting substrate provided with the semiconductor device, the mounting substrate having a front mounting surface on which the electronic component is mounted and a rear mounting surface on a back side relative to the front mounting surface.

An eleventh aspect of the present disclosure provides the module member according to the tenth aspect, wherein at least a portion of the semiconductor device is provided inside the mounting substrate.

A twelfth aspect of the present disclosure provides the module member according to the eleventh aspect, wherein the semiconductor device is exposed at the front mounting surface and the rear mounting surface.

A thirteenth aspect of the present disclosure provides the module member according to the tenth aspect, wherein the semiconductor device is mounted on at least one of the front mounting surface and the rear mounting surface.

A fourteenth aspect of the present disclosure provides the module member according to any one of the tenth to thirteenth aspects, wherein when viewed along the thickness direction, at least a portion of the semiconductor device and at least a portion of the electronic component are located at an overlapping position.

A fifteenth aspect of the present disclosure provides a circuit board comprising the module member according to any one of the tenth to fourteenth aspects; and a main substrate having the module member mounted on a front surface thereof. The semiconductor device is located between the mounting substrate and the main substrate.

Furthermore, the effects of each embodiment can be achieved by appropriately combining any of the various embodiments described above.

Although the present disclosure has been fully described in relation to preferred embodiments with reference to the drawings as appropriate, various modifications and alterations will be obvious to those skilled in the art. Such modifications and alterations should be understood to be included within the scope of the present disclosure as defined in the appended claims, as long as such modifications and alterations do not fall outside that scope.

What is claimed is:

1. A semiconductor device comprising:
a semiconductor substrate having one main surface and an other main surface spaced apart from the one main surface in a thickness direction and facing in an opposite direction from the one main surface in the thickness direction, the semiconductor substrate having at least one trench in the one main surface, and a hole that extends along the thickness direction, is open in at least one of the one main surface and the other main surface, and has a larger area than one of the trenches when viewed along the thickness direction;
a capacitance section at least inside the trench and including a dielectric layer and two electrode layers sandwiching the dielectric layer therebetween; and
a filling portion inside the hole and including a conductive material.

2. The semiconductor device according to claim 1, further comprising:
a conductive outer terminal on at least one of the one main surface and the other main surface, the outer terminal contacting the filling portion.

3. The semiconductor device according to claim 1, further comprising:
a conductive dummy terminal on at least one of the one main surface and the other main surface, the dummy terminal not electrically connected to other conductive parts of the semiconductor device.

4. The semiconductor device according to claim 1, wherein
the filling portion includes
an embedded layer including resin,
a conductive layer including a conductive material and surrounding the embedded layer when viewed along the thickness direction,
a barrier layer including a conductive material and surrounding the conductive layer when viewed along the thickness direction, and
an isolation layer including an insulating material and surrounding the barrier layer when viewed along the thickness direction.

5. The semiconductor device according to claim 1, wherein
the hole is open at one of the one main surface and the other main surface, and has a bottom at another one of the one main surface and the other main surface.

6. The semiconductor device according to claim 5, wherein
the hole includes
a side surface extending from one of the one main surface and the other main surface toward another one of the one main surface and the other main surface, and
a bottom surface connected to an end portion of the side surface at a side where the other one of the one main surface and the other main surface is located, and
a boundary portion between the side surface and the bottom surface is a curved surface.

7. The semiconductor device according to claim 5, wherein
a length of the hole in the thickness direction is greater than a length of the trench in the thickness direction.

8. The semiconductor device according to claim 1, wherein
the filling portion includes
a conductive layer including a conductive material and extending from one end portion to an other end portion of the hole in the thickness direction, and
a magnetic layer including a magnetic material and extending from the one end portion to the other end portion of the hole in the thickness direction.

9. The semiconductor device according to claim 8, wherein
the conductive layer penetrates through the magnetic layer in the thickness direction.

10. A module member comprising:
the semiconductor device according to claim 1;
an electronic component; and
a mounting substrate having the semiconductor device, the mounting substrate having a front mounting surface on which the electronic component is mounted and a rear mounting surface on a back side relative to the front mounting surface.

11. The module member according to claim 10, wherein at least a portion of the semiconductor device is inside the mounting substrate.

12. The module member according to claim 11, wherein
the semiconductor device is exposed at the front mounting surface and the rear mounting surface.

13. The module member according to claim 10, wherein
the semiconductor device is mounted on at least one of the front mounting surface and the rear mounting surface.

14. The module member according to claim 10, wherein
when viewed along the thickness direction, at least a portion of the semiconductor device and at least a portion of the electronic component are at an overlapping position.

15. A circuit board comprising:
the module member according to claim 10; and
a main substrate having the module member mounted on a front surface thereof,
wherein the semiconductor device is between the mounting substrate and the main substrate.

16. The semiconductor device according to claim 2, further comprising:
a conductive dummy terminal on at least one of the one main surface and the other main surface, the dummy terminal not electrically connected to other conductive parts of the semiconductor device.

17. The semiconductor device according to claim 2, wherein
the filling portion includes
an embedded layer including resin,
a conductive layer including a conductive material and surrounding the embedded layer when viewed along the thickness direction,
a barrier layer including a conductive material and surrounding the conductive layer when viewed along the thickness direction, and
an isolation layer including an insulating material and surrounding the barrier layer when viewed along the thickness direction.

18. The semiconductor device according to claim 2, wherein
the hole is open at one of the one main surface and the other main surface, and has a bottom at another one of the one main surface and the other main surface.

19. The semiconductor device according to claim 6, wherein
a length of the hole in the thickness direction is greater than a length of the trench in the thickness direction.

20. The semiconductor device according to claim 2, wherein
the filling portion includes
a conductive layer including a conductive material and extending from one end portion to an other end portion of the hole in the thickness direction, and
a magnetic layer including a magnetic material and extending from the one end portion to the other end portion of the hole in the thickness direction.
